(19) United States
(12) Patent Application Publication
(10) Pub. No.: US 2020/0111400 A1
(43) Pub. Date: Apr. 9, 2020

(54) DISPLAY DEVICE

(71) Applicant: SHARP KABUSHIKI KAISHA, Sakai City (JP)

(72) Inventors: HIROMI ENOMOTO, Sakai City (JP); YOJI INUI, Sakai City (JP)

(21) Appl. No.: 16/595,886

(22) Filed: Oct. 8, 2019

Related U.S. Application Data
(60) Provisional application No. 62/743,400, filed on Oct. 9, 2018.

(51) Int. Cl. G09G 3/20; H01L 27/32

(52) U.S. Cl. CPC G09G 3/2003; H01L 27/322; G09G 2300/0452; H01L 27/3213

(57) ABSTRACT

A display device includes a display panel, and a lighting device, a pixel controller, and a light source controller. The display panel includes colored pixels and a white pixel. The lighting device includes a white light source configured to emit light to exhibit a white color and a color adjusting light source configured to emit light tinged with a complementary color to a color with which light transmitted through the white pixel is tinged. The pixel controller is configured to control driving of the colored pixels and the white pixel. The light source controller is configured to control the white light source and the color adjusting light source to turn on the white light source when the colored pixels are driven and to turn on the color adjusting light source in addition to the white light source when the white pixel is driven in addition to the colored pixels.

### CROSS REFERENCE TO RELATED APPLICATION

This application claims priority from U.S. Provisional Patent Application No. 62/743,400 filed on Oct. 9, 2018. The entire contents of the priority application are incorporated herein by reference.

### TECHNICAL FIELD

The technology described herein relates to a display device.

### BACKGROUND ART

An example of a conventional display device is described in Japanese Unexamined Patent Application Publication No. 2013-7857. The display device obtains an RGB value that specifies the color of light passing through a liquid crystal panel on the assumption that a backlight having color components emits white light, calculates a first RGB value associated with the transmittance of the liquid crystal panel on the basis of the RGB value, and drives the liquid crystal panel on the basis of the first RGB value. When the light from the backlight having passed directly through a white pixel, a problem, that is, a change in the hue of light to be displayed on the liquid crystal panel may occur because of the color of light that has passed through the white pixel. In the backlight provided with RGB trichromatic LEDs and light having a white or another color emitted by controlling each LED, such a problem is less likely to occur. Specifically, on the assumption that white light is emitted from the backlight, by calculating a liquid crystal panel tone value in response to the color of light emitted by the backlight, the problem of the change in hue is prevented.

Since the display device described in Patent Document 1 mentioned above calculates the liquid crystal panel tone value in response to the color of light emitted by the backlight, it is necessary to prepare a device for performing the calculation and to set up the device. However, it is sometimes difficult to prepare such a device and/or set up the device, and the display device described in Patent Document 1 mentioned above is not easily adaptable to that case.

### SUMMARY

The technology described herein has been completed in view of these circumstances, and an object thereof is to suppress occurrence of color unevenness easily.

A display device includes: a display panel including colored pixels exhibiting different colors and a white pixel exhibiting a white color; a lighting device including at least one white light source configured to emit light to exhibit a white color and at least one color adjusting light source configured to emit light tinged with a color that is a complementary color to a color with which light transmitted through the white pixel is tinged; a pixel controller configured to control driving of the colored pixels and the white pixel; and a light source controller configured to control the at least one white light source and the at least one color adjusting light source to turn on the at least one white light source when the colored pixels are driven by the pixel controller and to turn on the at least one color adjusting light source in addition to the at least one white light source when the white pixel is driven by the pixel controller in addition to the colored pixels.

According to the technology described herein, occurrence of color unevenness can be easily suppressed.

### BRIEF DESCRIPTION OF THE DRAWINGS

FIG. 1 is a cross sectional view of a liquid crystal display device according to a first embodiment.

FIG. 2 is a circuit diagram illustrating a pixel array in a display region of an array substrate constituting a liquid crystal panel provided in the liquid crystal display device.

FIG. 3 is a plan view illustrating a color filter and pixel array in a display region of a CF substrate constituting the liquid crystal panel.

FIG. 4 is a plan view of a backlight device provided in the liquid crystal display device.

FIG. 5 is a block diagram illustrating an electrical configuration of the liquid crystal display device.

FIG. 6 is a circuit diagram representing an electrical connection configuration of LEDs in the backlight device.

FIG. 7 is a CIE 1931 chromaticity diagram illustrating white color reference coordinates.

FIG. 8 is a CIE 1931 chromaticity diagram illustrating a chromaticity change between a case where the white pixel is driven and a case where the white pixel is not driven.

FIG. 9 is a plan view of a backlight device according to a second embodiment.

FIG. 10 is a circuit diagram representing an electrical connection configuration of LEDs in the backlight device.

FIG. 11 is a plan view of a backlight device according to a third embodiment.

FIG. 12 is a plan view of the backlight device according to a fourth embodiment.

FIG. 13 is a circuit diagram representing an electrical connection configuration of LEDs in the backlight device.

### DETAILED DESCRIPTION

### First Embodiment

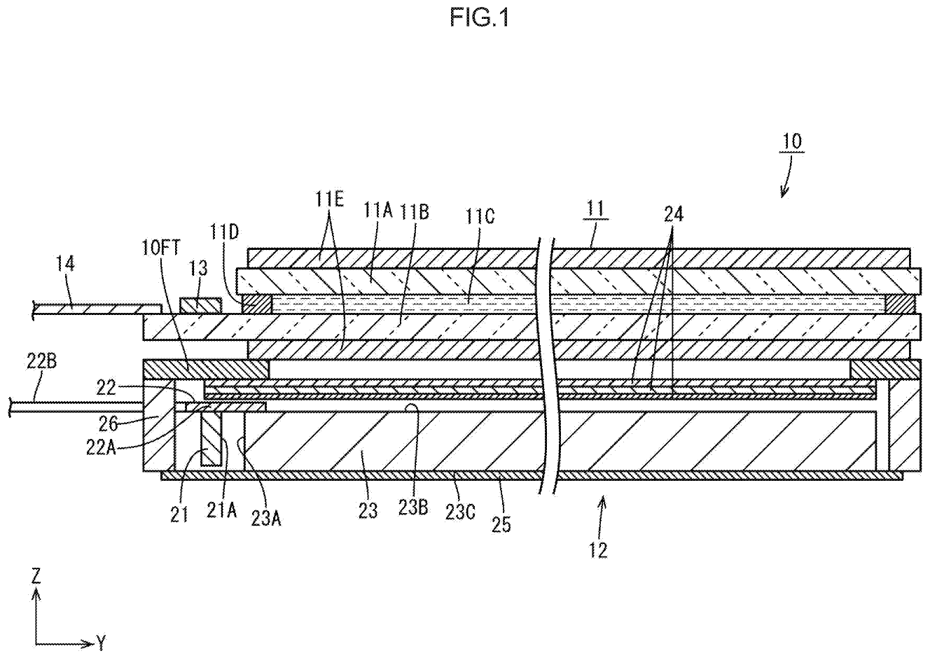

A first embodiment will be described with reference to FIGS. 1 to 8. In the first embodiment, a liquid crystal display device 10 will be illustrated. It should be noted that an X axis, a Y axis, and a Z axis are shown in part of each drawing, and depiction is made such that the direction of each axis is coincident with a direction shown in each drawing. It should be noted that the upper side in FIG. 1 is defined as front side, and the lower side in FIG. 1 is defined as back side.

The liquid crystal display device 10 is at least provided with a liquid crystal panel (display panel) 11 for displaying an image and a backlight device (lighting device) 12 that is an external light source disposed behind the liquid crystal panel 11 for irradiating the liquid crystal panel 11 with light for display, as shown in FIG. 1. The liquid crystal panel 11 and the backlight device 12 are fixed with a light-shielding frame-like fixing tape 10FT. The liquid crystal display device 10 according to the first embodiment is one used for a mobile information terminal such as a smartphone, for example. For this reason, the screen size of the liquid crystal panel 11 constituting the liquid crystal display device 10 is generally a size classified into small size (for example, about several inches).

The liquid crystal panel 11 has a configuration in which a liquid crystal layer 11C containing liquid crystal molecules that are matter whose optical properties change with electric field application is held between a pair of substrates 11A, 11B made of a glass that is substantially transparent and has excellent translucency, as shown in FIG. 1. In addition, the liquid crystal panel 11 has a seal portion 11D interposed between outer peripheral edges of the pair of substrates 11A, 11B so as to enclose the liquid crystal layer 11C to seal the liquid crystal layer 11C, and a pair of polarizers 11E attached to outer faces of the pair of substrates 11A, 11B. Of the pair of substrates 11A, 11B, one disposed on the front side is a CF substrate (opposite substrate) 11A, and the other disposed on the back side is an array substrate (active matrix substrate, TFT substrate). The liquid crystal panel 11 has a display region where an image is displayed in a central portion of the screen, and a non-display region where an image is not displayed in a bezel-like outer peripheral portion enclosing the display region in the screen. In the non-display region in the array substrate, a driver (drive circuit portion) 13 and a flexible substrate 14 are mounted as components for supplying various signals to the display region.

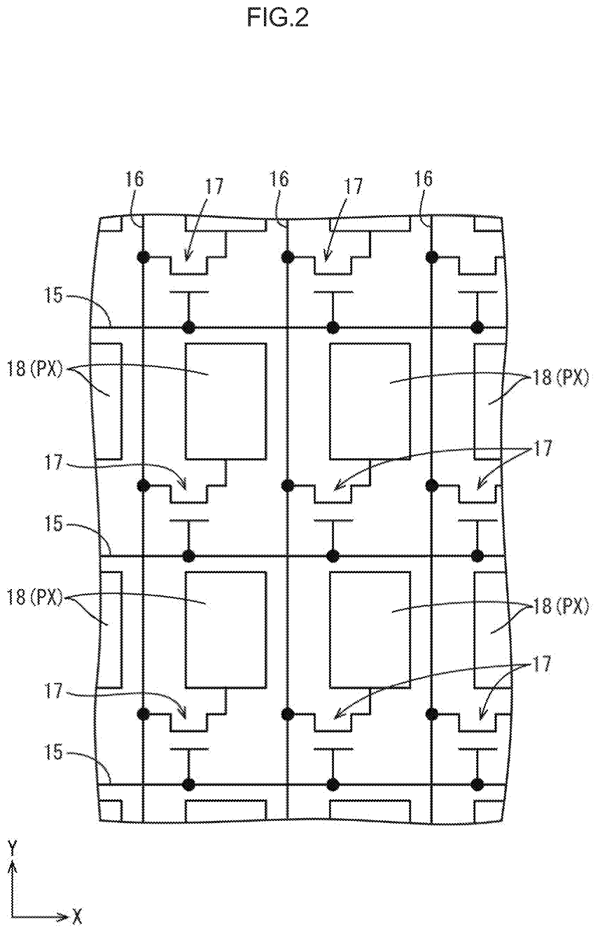

On an inner face side in the display region of the array substrate 11B, as shown in FIG. 2, a large number of gate lines (scanning lines) 15 and source lines (signal lines, data lines) 16 arranged in a grid pattern are disposed, and a TFT 17 that is a switching element and a pixel electrode 18 are provided in the vicinity of each intersection. The gate line 15 extends along the X-axis direction horizontally across the display region and is connected to a gate electrode of each TFT 17, whereas the source line 16 extends along the Y-axis direction vertically across the display region and is connected to a source electrode of each TFT 17. The large number of gate lines 15 are arranged side by side at intervals along the Y-axis direction, whereas the large number of source lines 16 are arranged at intervals along the X-axis direction. The larger number of TFTs 17 and the large number of pixel electrodes 18 are arranged in a plane in a matrix (rows and columns) side by side along the X-axis direction and the Y-axis direction, and the pixel electrode 18 is connected to a drain electrode of the TFT 17. The TFT 17 is driven on the basis of a scanning signal supplied to the gate line 15, and accordingly the pixel electrode 18 is charged with a potential based on an image signal (signal, data signal) supplied to the source line 16.

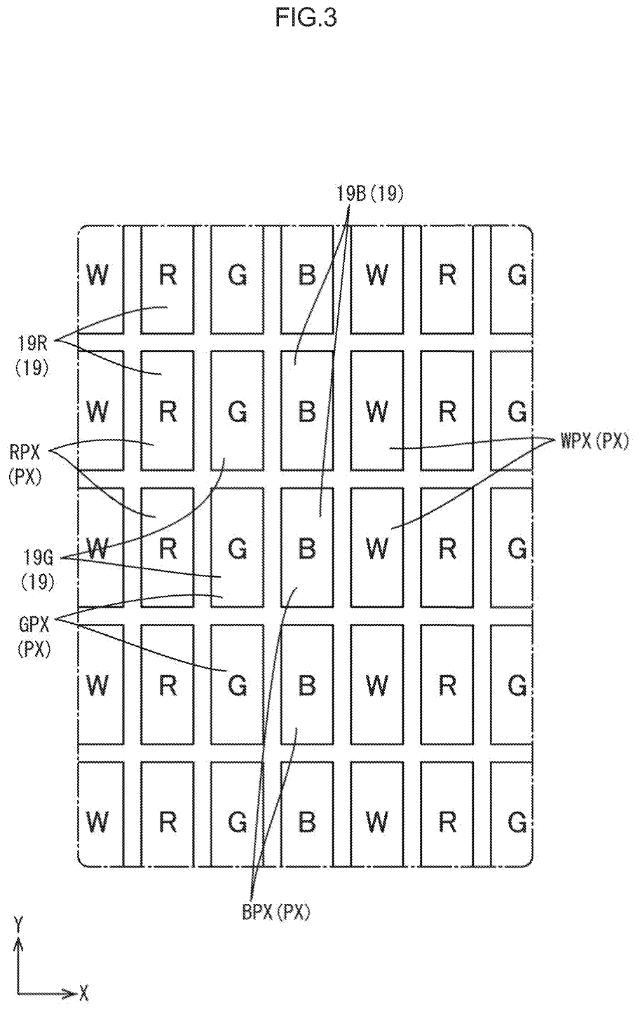

By contrast, on an inner face side of the display region of the CF substrate 11A, as shown in FIG. 3, trichromatic color filters 19 disposed so as to overlap with the respective pixel electrodes 18 and a light-shielding portion (black matrix) 20 separating adjacent color filters from each other is at least provided. The color filters 19 include three colors: a red color filter 19R exhibiting a red color for selectively transmitting red light belonging to a red wavelength range (about 600 nm to about 780 nm); a blue color filter 19B exhibiting a blue color for selectively transmitting blue light belonging to a blue wavelength range (about 420 nm to about 500 nm; and a green color filter 19G exhibiting a green color for selectively transmitting green light belonging to a green wavelength range (about 500 nm to about 570 nm). A set of the red color filter 19R, the green color filter 19G and the blue color filter 19B is arranged side by side repeatedly along the X-axis direction, but the color filter 19 is not formed between the blue color filter 19B and a red color filter 19R in the next set. It is preferred that a site of non-formation of the color filter 19 in the CF substrate 11A be filled with a colorless transparent resin material having a thickness equivalent to the color filter 19. The color filter 19 and the site of non-formation of the color filter 19 are so disposed as to overlap as viewed in plane with each pixel electrode 18 (see FIG. 2) of the array substrate 11B, and constitutes a pixel PX together with each pixel electrode 18. A large number of pixels PX are arranged side by side in a matrix in relation to the X-axis direction and the Y-axis direction within a panel plane of the liquid crystal panel 11. The pixel PX includes a red pixel RPX containing the red color filter 19R and exhibiting a red color, a blue pixel BPX containing the blue color filter 19B and exhibiting a blue color, a green pixel GPX containing the green color filter GPX and exhibiting a green color, and a white pixel WPX containing the site of non-formation of the color filter 19 and exhibiting a white color. Of them, the red pixel RPX, the blue pixel BPX and the green pixel GPX can be said to be “colored pixels RPX, BPX, GPX” exhibiting specific colors different from each other. The white pixel WPX is colorless and transparent, capable of transmitting almost all visible light, and has no wavelength selectivity. That is, the white pixel WPX transmits all of the red light, the blue light, the green light, and the like, thereby exhibiting a white color. In addition, on either the CF substrate 11A or the array substrate 11B, a common electrode made of the same transparent electrode material as the pixel electrode 18 and disposed so as to overlap with the pixel electrode 18 at an interval is provided. A predetermine electric field is applied to the liquid crystal layer on the basis of a potential difference occurring between the common electrode and each pixel electrode 18, and thereby the liquid crystal panel 11 enables each pixel PX to perform predetermined tone display.

Next, a backlight device 12 will be described. The backlight device 12 is at least provided with an LED (Light-Emitting Diode) 21 that is a light source, an LED substrate (light source substrate) 22 mounted with the LED 21, a light guide plate 23 for guiding light from the LED 21, an optical sheet (optical member) 24 overlaid on the front side of the light guide plate 23, a reflective sheet (reflective member) 25 overlaid on the back side of the light guide plate 23, and a frame-like frame 26 enclosing the LED 21, the light guide plate 23, the optical sheet 24, and the like. The backlight device 12 is of an edge-lit (side-lit) type that is a one-sided light entry type in which the light of the LED 21 enters the light guide plate 23 only from one side in relation to the Y-axis direction. Next, each component of the backlight device 12 will be described in detail.

The LED 21 has a configuration in which an LED chip (light-emitting element, LED element) is sealed with a sealing material on a substrate portion firmly attached to the LED substrate 22. The LED 21 is of a so-called side emission type in which a face adjacent to a face mounted on the LED substrate 22 serves as a light-emitting face 21A. The LED chip is a semiconductor composed of a semiconductor material such as InGaN, for example, and emits visible light in a predetermined wavelength range when a voltage is applied in a forward direction. The LED 21 at least includes a white LED (white light source) 33 for emitting light to show a white color. The white LED 33 has a blue LED chip (blue light-emitting element, blue LED element) that emits blue light monochromatically, for example, as an LED chip, and has a sealing material blended dispersedly with a phosphor (yellow phosphor, green phosphor, red phosphor, and the like), thereby emitting white light as a whole.

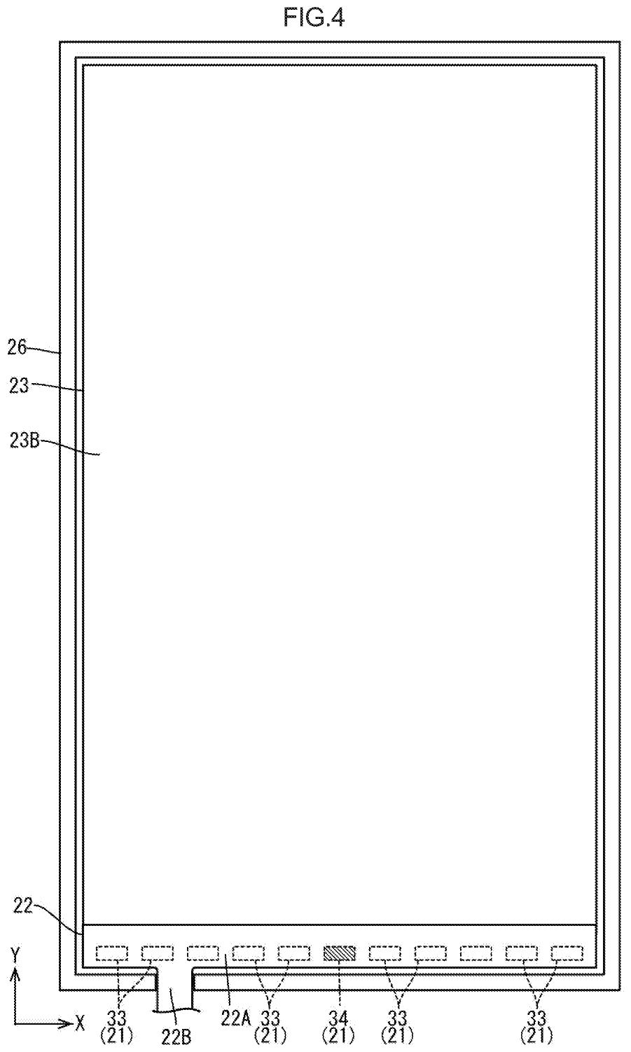

The LED substrate 22 is disposed on the front side with respect to the frame 26 and the light guide plate 23, and so disposed as to be sandwiched by these and the liquid crystal panel 11, as shown in FIGS. 1 and 4. The LED substrate 22 has the shape of a film (the shape of a sheet) made of an insulating material and having flexibility. The LED substrate 22 is composed of an LED mounting portion 22A extending along the X-axis direction (a longitudinal direction of a light entry end face 23A) and having LEDs 21 (eleven in FIG. 4) each mounted thereon so as to be arranged side by side at intervals, and a led-out portion 22B led out from the LED mounting portion 22A to the outside of the frame 26 along the Y-axis direction. On the back side face of the LED substrate 22, the LEDs 21 are surface-mounted in a mutually spaced arrangement in relation to the X-axis direction, and also patterned with a line for feeding power to each LED 21.

The light guide plate 23 is a substantially transparent synthetic resin material (for example, an acrylic resin such as PMMA, polycarbonate, or the like), and has a sufficiently higher refractive index than air. The light guide plate 23 has a vertically-long plate shape and is so accommodated as to be enclosed with the frame 26 and also disposed in a position immediately below the liquid crystal panel 11 and the optical sheet 24, as shown in FIGS. 1 and 4, and its long-side direction, short-side direction, and thickness direction are coincident with the X-axis direction, the Y-axis direction, and the Z-axis direction in each drawing, respectively. One (the left side shown in FIG. 1) short-side end face of outer peripheral end faces of the light guide plate 23 is a light entry end face (light source facing end face) 23A facing the LED 21 and letting the light from the LED 21 in. This light entry end face 23A is parallel with the light-emitting face 21A of the LED 21, and simultaneously extends rectilinearly along the X-axis direction (a direction in which the LEDs 21 are arranged side by side). The light guide plate 23 has a pair of front and back plate faces, and, of them, a plate face toward the front side (the liquid crystal panel 11 side) is a light exit plate face 23B letting the light out toward the liquid crystal panel 11, and a plate face toward the back side is a light exit opposite plate face 23C opposite to the light exit plate face 23B. The light exit plate face 23B is parallel with a panel face of the liquid crystal panel 11, and faces the plate face of the liquid crystal panel 11 with the optical sheet 24 therebetween. By such a configuration, the light guide plate 23 has a function of introducing the light emitted along the Y-axis direction from the LED 21 through the light entry end face 23A, and also propagating the light inside, thereafter raising the light along the Z-axis direction, and then letting the light from the light exit plate face 23B out toward the optical sheet 24 and the liquid crystal panel 11 (the front side, light outgoing side).

The optical sheet 24 is so disposed as to lie between the liquid crystal panel 11 and the light guide plate 23, thereby transmitting the outgoing light from the light guide plate 23 and simultaneously letting the transmitted light out toward the liquid crystal panel. 11 while exerting a predetermined optical effect on it. Multiple (three in the first embodiment) optical sheets 24 are provided, and specific types thereof include, for example, a diffusion sheet, a lens sheet (prismatic sheet), a reflective polarizing sheet, and the like, and any of them may be appropriately selected and used.

The reflective sheet 25 is so disposed as to cover the light exit opposite plate face 23C of the light guide plate 23, as shown in FIG. 1. The reflective sheet 25 has excellent light reflectivity, and is capable of raising light leaking from the light exit opposite plate face 23C of the light guide plate 23 efficiently toward the front side (the light exit plate face 23B side). The reflective sheet 25 has such a large outer shape that the light guide plate 23 is entirely within the reflective sheet 25, and has one short-side end disposed so as to project toward the LED 21 beyond the light entry end face 23A.

The frame 26 is made of a synthetic resin (for example, made of polycarbonate) having a surface exhibiting a white color and, as shown in FIG. 1, has an outer shape formed in such a large frame shape that the light guide plate 23 is entirely within the frame 26. The frame 26 is so disposed as to enclose the LEDs 21 and the light guide plate 23, and the like, collectively. An adhesive material on the back face side of the fixture tape 10FT having a light shielding property described above is firmly attached to a front side face of the frame 26, and thereby the frame 26 is fixed to the liquid crystal panel 11 via the fixture tape 10FT.

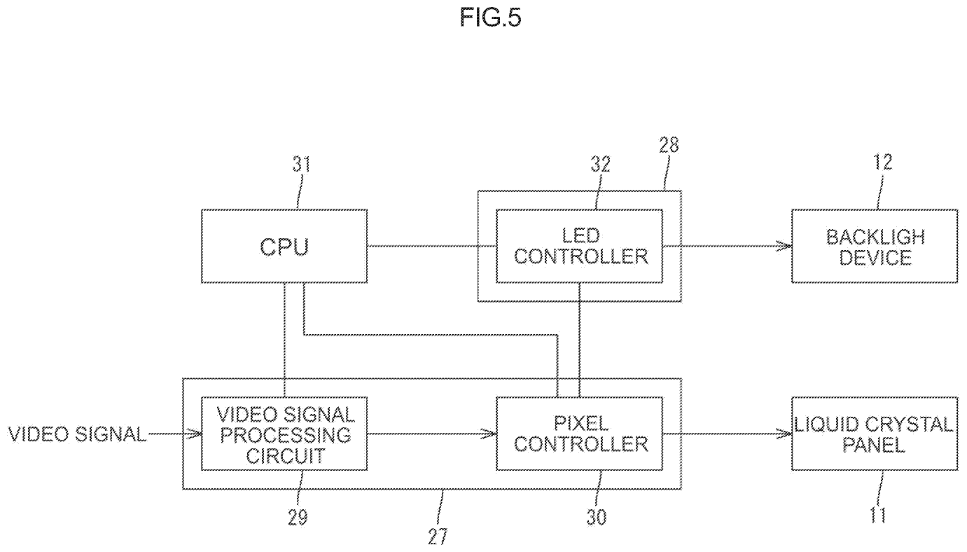

The liquid crystal display device 10 is provided with a panel controller 27 for controlling the liquid crystal panel 11 and a backlight controller (lighting controller) 28 for controlling the backlight device 12, as shown in FIG. 5. On them, the panel controller 27 has a video signal processing circuit 29 for processing a video signal and a pixel controller 30 for controlling driving of the red pixel RPX, the green pixel GPX and the blue pixel BPX on the basis of an output signal from the video signal processing circuit 29, and is provided on a control board. A CPU 31 for controlling the respective operations of the video signal processing circuit 29, the pixel controller 30 and an LED controller 32 described later is provided on the control board. The pixel controller 30 scans a pixel group composed of red pixels RPX, green pixels GPX, and blue pixels BPX arranged side by side repeatedly in a row direction, sequentially along a column direction. Specifically, scanning of each pixel RPX, GPX, BPX performed by the pixel controller 30 starts from a pixel group at an upper end of the screen, and performed sequentially to a pixel group at a lower end of the screen (see FIG. 3). On the other hand, the backlight controller 28 has the LED controller (light source controller) 32 for controlling driving of the LED 21 on the basis of an output signal from the video signal processing circuit 29, and is provided on an LED drive circuit board. The operation of the LED controller 32 is controlled by the CPU 31 of the control board and, in detail, synchronized with the operation of the pixel controller 30 as described later.

By the way, in a conventional display device, since the liquid crystal panel tone value is calculated in response to the color of light emitted by the backlight device, it is necessary to prepare a device (for example, an IC) for performing the calculation and to perform setting of the device. However, there is a case where it is difficult to prepare such a device and/or perform setting thereof, and the conventional display device is not easily adaptable to that case. In addition, even in the backlight device using a white light emitting type LED as a light source, there is a case where light transmitted through a white pixel may be tinted, and in such a case, if adjustment of the liquid crystal panel tone value is performed like a conventional display device, a reduction in luminance may occur. Specifically, if the light transmitted through the white pixel is tinted with a magenta color, the liquid crystal panel tone value may be adjusted such that the tone values of the red pixel and the blue pixel are lower than their original values, but a reduction in overall luminance is caused by making the tone values of the red pixel and the blue pixel lower than their original values. It should be noted that it is inferred that the reason why the light transmitted through the white pixel is tinted is because, for example, in the process of the light emitted from the white LED passing through the light guide plate, each optical sheet and the polarizer, and the like, before reaching the white pixel, light of a specific wavelength is absorbed by any of those members. Alternatively, it is also inferred that the white LED itself is responsible for that because the white LED used in the backlight device emits white light as a whole but can emit white light tinged slightly with a specific color, depending on the chromaticity rank.

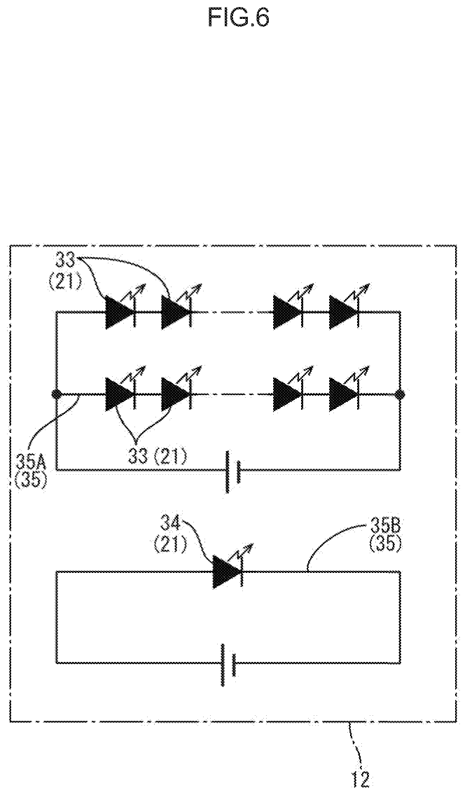

Therefore, the LED 21 provided in the backlight device 12 according to the first embodiment includes a color adjusting LED (color adjusting light source) 34 for emitting light tinged with a color that is a complementary color to a color tinging the light transmitted through the white pixel WPX, in addition to the white LED 33 for emitting white light, as already described, as shown in FIGS. 4 and 6. It should be noted that, in FIG. 4, the color adjusting LED 34 is shown by hatching lines so as to be distinguished from the white LED 33. Specifically, in the first embodiment, since the configuration in which the light transmitted through the white pixel WPX exhibits a magenta color is assumed, the color adjusting LED 34 emits light having a green color that is a complementary color to a magenta color. A green LED having a green LED chip (green light-emitting element, green LED element) that emits green monochromatic light, for example, is used as the color adjusting LED 34. It should be noted that, in the color adjusting LED 34, the sealing material for sealing the green LED chip is made of a transparent resin material not containing a phosphor, and the emitted light of the green LED chip is coincident with the light (green monochromatic light) emitted by the color adjusting LED 34. A green LED thus configured is a widely-distributed product, and procurable inexpensively. On the LED substrate 22, as shown in FIG. 4, the white LEDs 33 and the color adjusting LED 34 are so mounted as to be mixed together, and the number of color adjusting LEDs 34 installed is only one, whereas the number of white LEDs 33 installed is more than one (ten in FIG. 4). The color adjusting LED 34 is disposed in the vicinity of a central position in relation to a length direction (X-axis direction) in the LED mounting portion 22A of the LED substrate 22. Therefore, the white LEDs 33 are divided into two groups by the color adjusting LED 34 disposed at the center. On the LED substrate 22, as shown in FIG. 6, an LED line portion 35 for feeding power to each LED 21 is formed. The LED line portion 35 includes two systems: a white LED line portion 35A connected to the white LEDs 33 and a color adjusting LED line portion 35B connected to the one color adjusting LED 34.

Then, the LED controller 32 controls the LED 21 according to the status of the pixel PX driven by the pixel controller 30. In detail, if the colored pixel RPX, BPX, GPX are selectively driven by the pixel controller 30, the LED controller 32 lights the white LED 33, but makes the color adjusting LED 34 unlit. By contrast, if the white pixel WPX is driven in addition to the colored pixels RPX, BPX, GPX by the pixel controller 30, the LED controller 32 lights not only the white LED 33 but also the color adjusting LED 334. That is, the LED controller 32 lights the white LED 33, regardless of whether or not the white pixel WPX is driven, while the pixels PX are being driven by the pixel controller 30, but selectively lights the color adjusting LED 34 only if the white pixel WPX is driven by the pixel controller 30. At this time, it is preferred that the amount of emitted light of the color adjusting LED 34 be adjusted in response to the intensity of a color tinging the light transmitted through the white pixel. In this manner, when the white pixel WPX is driven by the pixel controller 30, the light transmitted through the white pixel WPX contains light emitted from the white LED 33 and light emitted from the color adjusting LED 34. Since the color adjusting LED 34 emits light tinged with a green color that is a complementary color to a magenta color tinging the light transmitted through the white pixel WPX, the light transmitted through the white pixel WPX is whitened by additive color mixture of magenta light and green light and not easily tinged with a specific color. For this reason, even when the white pixel WPX is driven, color unevenness does not easily occur in an image displayed on the liquid crystal panel 11. Moreover, regarding the liquid crystal panel 11 and the pixel controller 30, it is unnecessary to prepare and/or set up a special device, and therefore the first embodiment is easily adaptable. In addition, since tinging color adjustment is performed by adding the color adjusting LED 34, as compared with the conventional case where the tone value associated with the colored pixels RPX, BPX, GPX in the liquid crystal panel 11 is adjusted, a reduction in luminance is avoided.

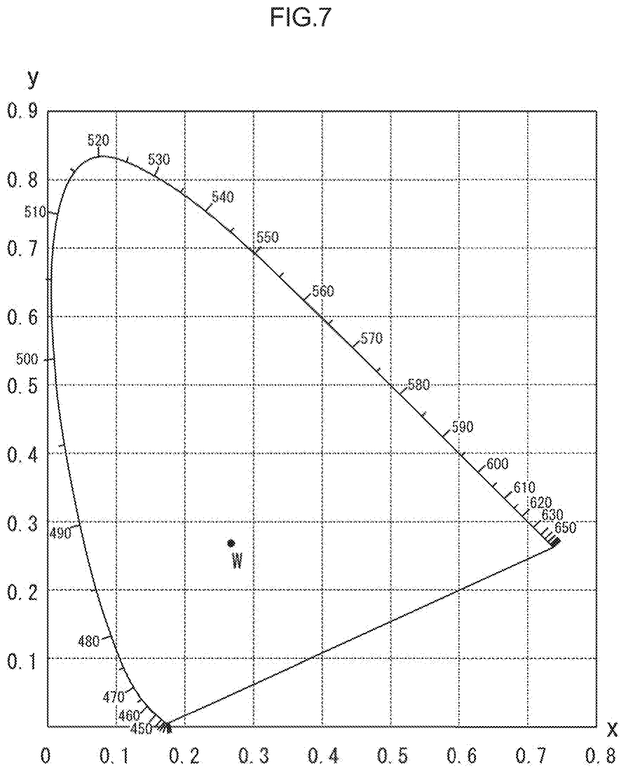

The first embodiment is thus configured, and next the actions thereof will be described. First, FIG. 7 is a CIE (Commission Internationale de l'Eclairage) 1931 chromaticity diagram. In the CIE 1931 chromaticity diagram shown in FIG. 7, an x value and a y value that are chromaticity values based on an X value, a Y value, a Z value that are tristimulus values in an XYZ color system are on the horizontal axis and the vertical axis. In the first embodiment, reference coordinates of “a white color” are, for example, (0.272, 0.277) in FIG. 7, and the chromaticity tends to shift toward a magenta color (the color becomes more magentaish) as the x value increases and the y value decreases from the white color reference coordinates, and conversely shift toward a green color (the color becomes more greenish) as the x value decreases and the y value increases. It should be noted that, in FIG. 7, the white color reference coordinates are plotted, and the plot is denoted by the letter “W”.

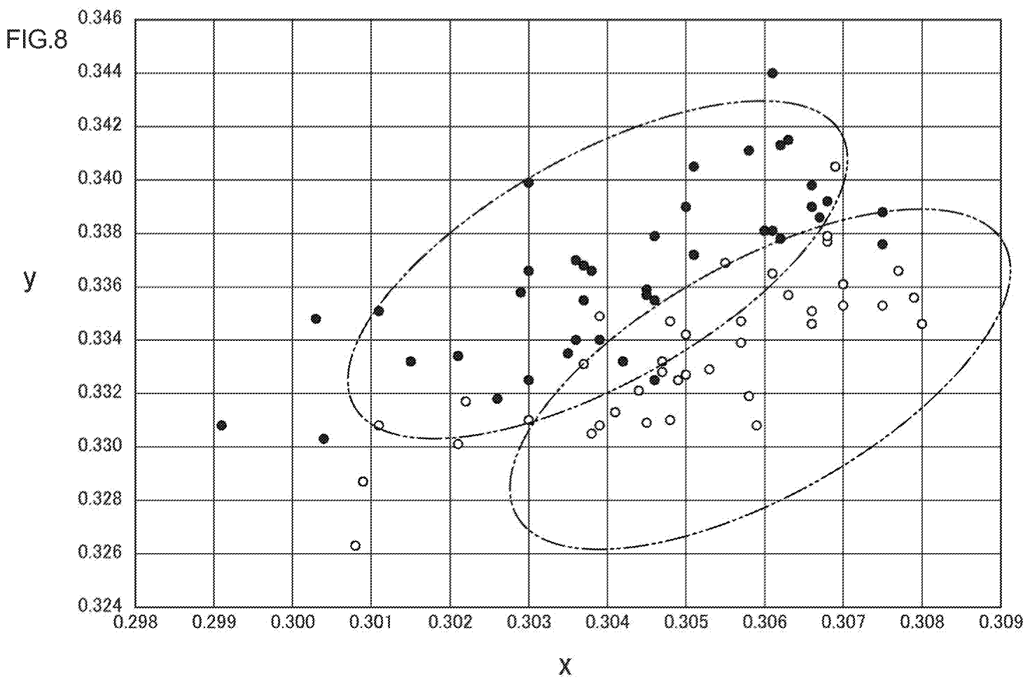

On the other hand, FIG. 8 is a chromaticity diagram exhibiting how the chromaticity changes between a case where the colored pixels RPX, BPX, GPX are selectively driven while the white LED 33 is being selectively driven and a case where the colored pixels RPX, BPX, GPX and the white pixel WPX are driven together while the white LED 33 is being selectively driven. In FIG. 8, a plot in the case where the white pixel WPX is not driven and a plot in the case where the white pixel WPX is driven are represented by “black circle” signs and “white circle” signs, respectively. In FIG. 8, “black circle” sings and “white circle” sings are plotted, and these are results of experiments in which liquid crystal display devices 10 were used and simultaneously each liquid crystal display device 10 displayed under various temperature conditions. Thereby, the influence of individual differences of the liquid crystal display device 10 and/or the influence of the temperature conditions is excluded. FIG. 8 shows that the chromaticity has a tendency to increase the x value but decrease the y value, that is, a tendency to be tinged with a magenta color when a switch from the state in which the white pixel WPX is not driven to the state in which the white pixel WPX is driven is made.

By contrast, in the liquid crystal display device 10 according to the first embodiment, if the color pixels RPX, BPX, GPX and the white pixel WPX are driven together by the pixel controller 30, the color adjusting LED 34 is turned on in addition to the white LED 33 by the LED controller 32. In this manner, the white pixel WPX is supplied with the light from the color adjusting LED 34 in addition to the light from the white LED 33. Thereby, the light transmitted through the white pixel WPX is whitened by additive color mixture of magenta light and green light and thus not easily tinged with a specific color. Specifically, the chromaticity is returned from the plot of the “white circle” signs in FIG. 8 exhibiting the unlit state of the color adjusting LED 34 to or to the vicinity of the plot of the “black circle” sings with lighting of the color adjusting LED 34, and thus whitening is achieved. For the above reason, a change in the hue of an image displayed on the liquid crystal panel 11 does not easily occur between the case where the white pixel WPX is not driven and the case where the white pixel WPX is driven, and thus an excellent display quality with color unevenness suppressed is obtained.

It should be noted that, when tone driving of the white pixel WPX is performed by the pixel controller 30 to adjust the amount of light transmitted through the white pixel WPX, it is preferred that the LED controller 32 control the color adjusting LED 34 so as to adjust the amount of emitted light of the color adjusting LED 34 in response to the tone value (the amount of transmitted light) of the white pixel WPX. In detail, when the white pixel WPX is driven with a low tone value, the amount of light transmitted through the white pixel WPX is small, and hence, even when the light transmitted through the white pixel WPX is tinted with a magenta color, the tinging color is light. On the other hand, when the white pixel WPX is driven with a high tone value, the amount of light transmitted through the white pixel WPX is large, and hence, when the light transmitted through the white pixel WPX is tinted with a magenta color, the tinging color is dark. Hence, if the amount of emitted light of the color adjusting LED 34 is fixed regardless of the tone value of the white pixel WPX, the ratio of magenta light and green light contained in the light transmitted through the white pixel WPX may be unbalanced, and thus the transmitted light may not properly be whitened. In this regard, when the white pixel WPX is driven with a low tone, if the color adjusting LED 34 is driven by the LED controller 32 such that the amount of emitted light of the color adjusting LED 34 is reduced, the green light of the color adjusting LED 34 contained in the light transmitted through the white pixel WPX is reduced. On the other hand, when the white pixel WPX is driven with a high tone, if the color adjusting LED 34 is driven by the LED controller 32 such that the amount of emitted light of the color adjusting LED 34 is increased, the green light of the color adjusting LED 34 contained in the light transmitted through the white pixel WPX is increased. From the above reason, the ratio of the magenta light and the green light contained in the light transmitted through the white pixel WPX is constantly optimized, and thus proper whitening can be achieved.

As described above, according to the liquid crystal display device (display device) 10 of the first embodiment is provided with the liquid crystal panel (display panel) 11 at least having the colored pixels RPX, BPX, GPX exhibiting different colors and the white pixel WPX exhibiting a white color, the backlight device (lighting device) 12 at least having the white LED (white light source) 33 for emitting light so as to show a white color and the color adjusting LED (color adjusting light source) 34 for emitting light tinged with a color that is a complementary color to a color tinging the light transmitted through the white pixel WPX, the pixel controller 30 for controlling driving of the colored pixels RPX, BPX, GPX and the white pixel WPX, and the LED controller (light source controller) 32 for controlling the white pixel WPX and the color adjusting LED 34 such that the white LED 33 is tuned on when the colored pixels RPX, BPX, GPX are driven by the pixel controller 30, and the color adjusting LED 34 is turned on in addition to the white LED 33 when the white pixel WPX is driven by the pixel controller 30 in addition to the colored pixels RPX, BPX, GPX.

In this manner, if the colored pixels RPX, BPX, GPX are selectively driven by the pixel controller 30 and simultaneously the white pixel WPX is turned on by the LED controller 32, the light emitted from the white LED 33 and exhibiting a white color is utilized to perform color display with the colored pixels RPX, BPX, GPX. By contrast, if the white pixel WPX is driven in addition to the colored pixels RPX, BPX, GPX by the pixel controller 30, since the white pixel WPX exhibiting a white color transmits the light from the backlight device 12 with low loss, enhancement of luminance associated with an image displayed on the liquid crystal panel 11 is achieved. By the way, a specific wavelength component of the light emitted from the white LED 33 may be absorbed by another member before reaching the white pixel WPX, and this may cause the light transmitted through the white pixel WPX to be tinged with a specific color. In addition, the white LED 33 emits light so as to show a white color but, in some cases, emits light tinged with a specific color, and in that case the light transmitted through the white pixel WPX is tinged with the specific color. In this regard, since the LED controller 32 lights the color adjusting LED 34 in addition to the white LED 33 if the white pixel WPX is driven in addition to the colors pixels RPX, BPX, GPX by the pixel controller 30, the light transmitted through the white pixel WPX consequently contains the light emitted from the white LED 33 and the light emitted from the color adjusting LED 34. Since the color adjusting LED 34 emits the light tinged with a color that is a complementary color to a color tinging the light transmitted through the white pixel WPX, the light transmitted through the white pixel WPX is whitened by additive color mixture and thus not easily tinged with a specific color. This makes unlikely color unevenness in an image displayed on the liquid crystal panel 11. Moreover, regarding the liquid crystal panel 11 and the pixel controller 30, it is unnecessary to perform preparation, setting, or the like, of a special device, and therefore the first embodiment is easily adaptable. In addition, since tinging color adjustment is performed by adding the color adjusting LED 34, as compared with the conventional case where the tone value associated with the colored pixels RPX, BPX, GPX in the liquid crystal panel 11 is adjusted, a reduction in luminance is avoidable.

In addition, the color adjusting LED 34 emits light exhibiting a red, green or blue color. This is suitable in terms of achieving a reduction in procurement cost associated with the color adjusting LED 34.

In addition, the color adjusting LED 34 emits light exhibiting a green color. In this manner, if the light transmitted through the white pixel WPX exhibits a magenta color, the light exhibiting a green color that is a complementary color to a magenta color is emitted by the color adjusting LED 34, and thus the light transmitted through the white pixel WPX is whitened by additive color mixture.

In addition, the white LEDs 33 are installed, and the number of color adjusting LEDs 34 installed is smaller than the number of white LEDs 33 installed. This makes unlikely luminance unevenness due to the color adjusting LED 34 unlit when the white LEDs 33 are turned on and the color adjusting LED 34 is unlit by the LED controller 32.

In addition, the pixel controller 30 controls driving of the white pixel WPX such that the amount of light transmitted through the white pixel WPX is adjusted, and the LED controller 32 controls the color adjusting LED 34 such that the amount of emitted light of the color adjusting LED 34 is adjusted in response to the amount of light transmitted through the white pixel WPX. In this manner, since driving of the white pixel WPX is controlled by the pixel controller 30 such that the amount of light transmitted through the white pixel WPX is adjusted, to what extent the luminance associated with an image displayed on the liquid crystal panel 11 is enhanced is adjustable. Even when the color tinging the white pixel WPX changes with the adjustment of the amount of light transmitted through the white pixel WPX, since the color adjusting LED 34 is controlled such that the amount of emitted light of the color adjusting LED 34 is adjusted in response to the amount of light transmitted through the white pixel WPX, the light transmitted through the white pixel WPX is properly whitened.

### Second Embodiment

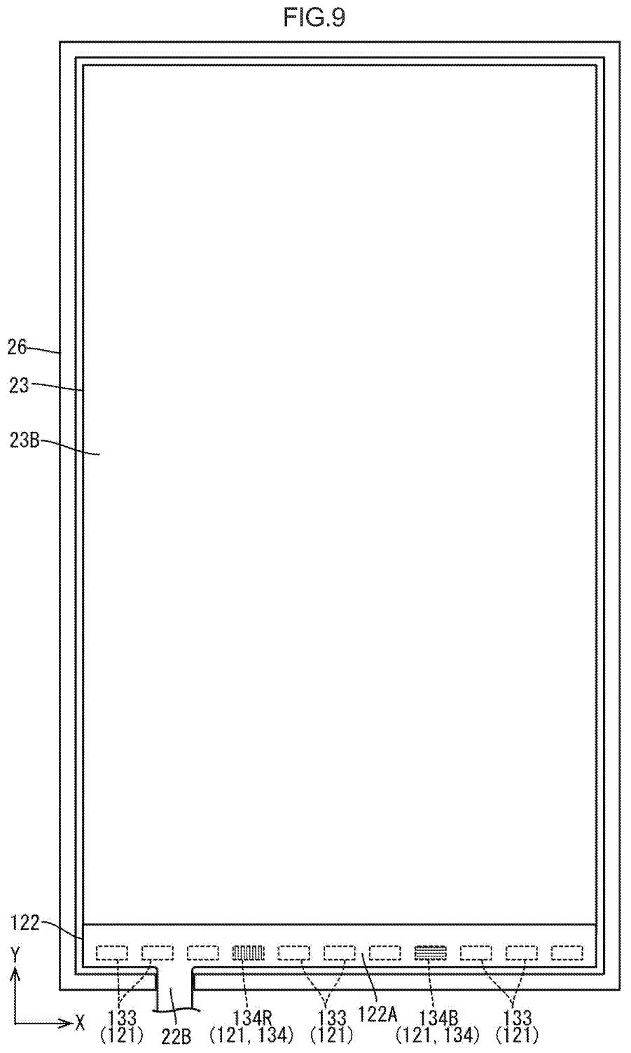

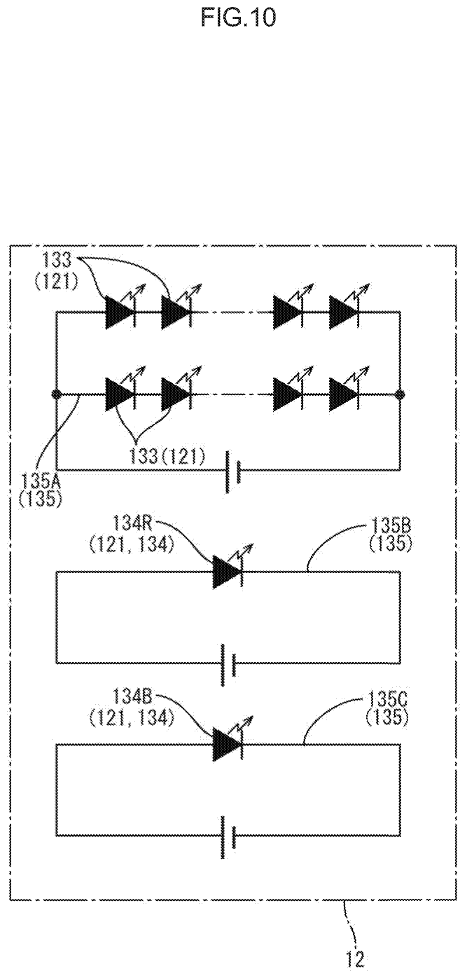

A second embodiment will be described with reference to FIG. 9 or 10. In the second embodiment, the liquid crystal display device 10 having a color adjusting LED 134 modified is illustrated. It should be noted that redundant descriptions of a structure, an action and an effect similar to those of the first embodiment described above will be omitted.

The color adjusting LED 134 according to the second embodiment includes two kinds: a red LED 134R that emits red light and a blue LED 134B that emits blue light, as shown in FIG. 9. That is, in the second embodiment, a configuration in which the light transmitted through the white pixel (see FIG. 3) exhibits an yellow or cyan color is assumed, and the LED controller (see FIG. 5) lights the blue LED 134B that emits light having a blue color that is a complementary color to an yellow color if the light transmitted through the white pixel exhibiting an yellow color, and lights the red LED 134R that emits light having a red color that is a complementary color to a cyan color if the light transmitted through the white pixel exhibits a cyan color. It should be noted that, in FIG. 9, the two kinds of color adjusting LEDs 134 are shown by hatching lines differently from each other in order to distinguish them. The red LED 134R that is the color adjusting LED 134 has a configuration in which a red LED chip (red light-emitting element, red LED element) that emits red monochromatic light, for example, is sealed with a sealing material composed of a transparent resin material not containing a phosphor. The blue LED 134B that is the color adjusting LED 134 has a configuration in which a blue LED chip (blue light-emitting element, blue LED element) that emits blue monochromatic light, for example, is sealed with a sealing material composed of a transparent resin material not containing a phosphor. Both the red LED 134R and the blue LED 134B thus configured are commonly distributed products, and procurable inexpensively. On the LED board 122, the white LED 133, and the red LED 134R and the blue LED 134B that are the color adjusting LEDs 134 are so mounted as to be mixed, the respective numbers of red LEDs 134R and blue LEDs 134B installed are one, whereas the number of white LEDs 133 installed is more than one (nine in FIG. 9). The red LED 134R and the blue LED 134B that are the color adjusting LEDs 134 are disposed in a central position on the right half of FIG. 9 and in a central position on the left half of FIG. 9, respectively. Therefore, the white LEDs 133 are divided into three groups by the red LED 134R and the blue LED 134B. The LED line portion 135 provided on the LED board 122 includes three systems: a white LED line portion 135A connected to the white LEDs 133; a red LED line portion 135B connected to the one red LED 134R; and a blue LED line portion 135C connected to the one blue LED 134B, as shown in FIG. 10.

Next, actions in the second embodiment will be described. First, the color tinging the light transmitted through the white pixel is inspected. In inspection, the white pixel is driven in addition to the colored pixels (see FIG. 3) by the pixel controller (see FIG. 5), and simultaneously the white LED 133 is turned on by the LED controller. In this state, the chromaticity associated with the light transmitted through the white pixel is measured, and the tinging color is inspected. As a result, if it is found that the light transmitted through the white pixel exhibits an yellow color, the blue LED 134B that emits light having a blue color that is a complementary color to an yellow color is set to be turned on and the red LED 134R is set to be unlit by the LED controller when the white pixel is driven. On the other hand, if it is found that the light transmitted through the white pixel exhibits a cyan color, the red LED 134R that emits light having a red color that is a complementary color to a cyan color is set to be turned on and the blue LED 134B is set to be unlit by the LED controller when the white pixel is driven. At this time, it is preferred that the amount of emitted light of the red LED 134R or the blue LED 134B be adjusted in response to the intensity of the color tinging the light transmitted through the white pixel. Further, if the light transmitted through the white pixel exhibits a color between an yellow color and a cyan color, both the red LED 134R and the blue LED 134B can also be set to be turned on by the LED controller when the white pixel is driven. At this time, the ratio of the amounts of emitted light of the red LED 134R and the blue LED 134B can be adjusted in response to the color tinging the light transmitted through the white pixel. This enables proper adaptation to even a complicated tinging color associated with the light transmitted through the white pixel.

As described above, according to the second embodiment, the color adjusting LEDs 134 for emitting light exhibiting different colors are provided. This also enables proper adaptation to a case where there are two or more kinds of tinging colors associated with the light transmitted through the white pixel, as compared with a possible case where only one color adjusting LED for emitting light monochromatically is provided.

In addition, the LED controller individually controls turn-on and turn-off of the color adjusting LEDs 134. This enables either one of the color adjusting LEDs 134 to be turned on and the other color adjusting LEDs 134 to be unlit, and also enables all the color adjusting LEDs 134 to be turned on. When the color adjusting LED 134 are turned on together, the amount of emitted light of each color adjusting LED 134 is also adjustable, and this enables proper adaptation to even a complicated tinging color associated with the light transmitted through the white pixel.

### Third Embodiment

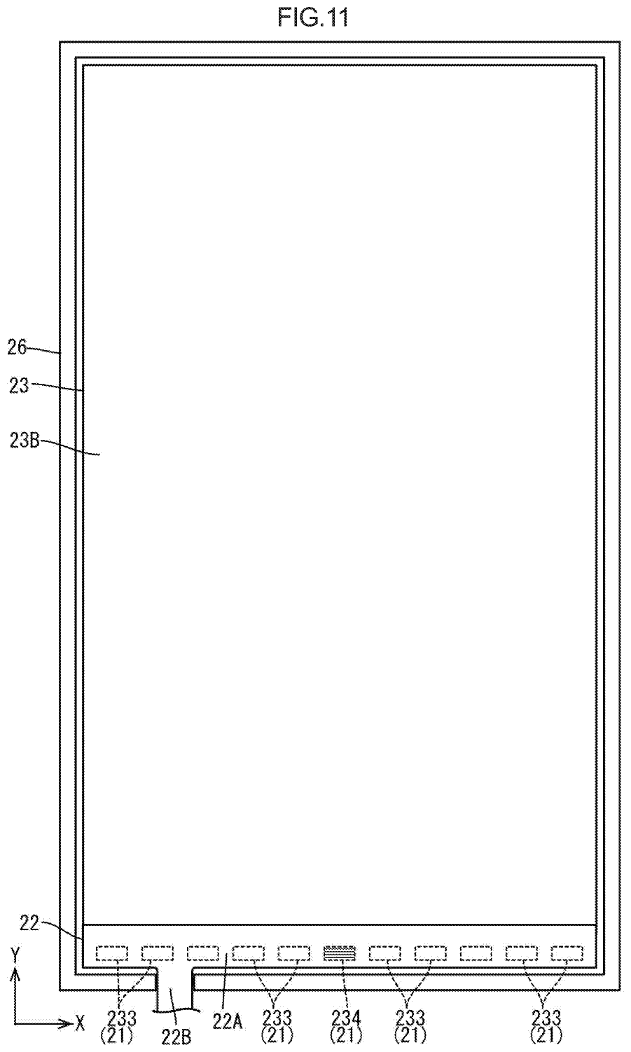

A third embodiment will be described with reference to FIG. 11. In the third embodiment, the liquid crystal display device 10 having a color adjusting LED 234 modified from the first embodiment described above is illustrated. It should be noted that redundant descriptions of a structure, an action and an effect similar to those of the first embodiment described above will be omitted.

The color adjusting LED 234 according to the third embodiment emits white light tinged with a blue color, as shown in FIG. 11. In detail, the color adjusting LED 234 has a blue LED chip that emits blue light monochromatically, for example, as an LED chip, and has a sealing material dispersedly blended with a predetermined phosphor, thereby emitting white light as a whole, and has a configuration similar to the white LED 233. Preferably, the color adjusting LED 234 has the same configuration as the white LED 233, and classified into a rank different from the white LED 233 (a rank in which bluish white light is emitted) according to rank classification associated with chromaticity. This reduces procurement cost associated with the white LED 233 and the color adjusting LED 234 as compared with the case where the color adjusting LED for emitting monochromatic light are prepared as a color adjusting LED separately from the white LED 233, like the first and second embodiments described above. In the third embodiment, a configuration in which the light transmitted through the white pixel (see FIG. 3) exhibits an yellow color, and the LED controller (see FIG. 5) lights the color adjusting LED 234 for emitting white light tinged with a blue color that is a complementary color to an yellow color when the white pixel is driven by the pixel controller.

As described above, according to the third embodiment, the color adjusting LED 234 emits white light tinged with a specific color. This enables an LED that emits white light different in chromaticity rank from the white LED 233 to be used when the color adjusting LED 234 is procured. Therefore, as compared with a possible case where an LED that emits monochromatic light other than white light is prepared as a color adjusting LED separately from the white LED 233, the third embodiment is suitable in terms of cost reduction.

### Fourth Embodiment

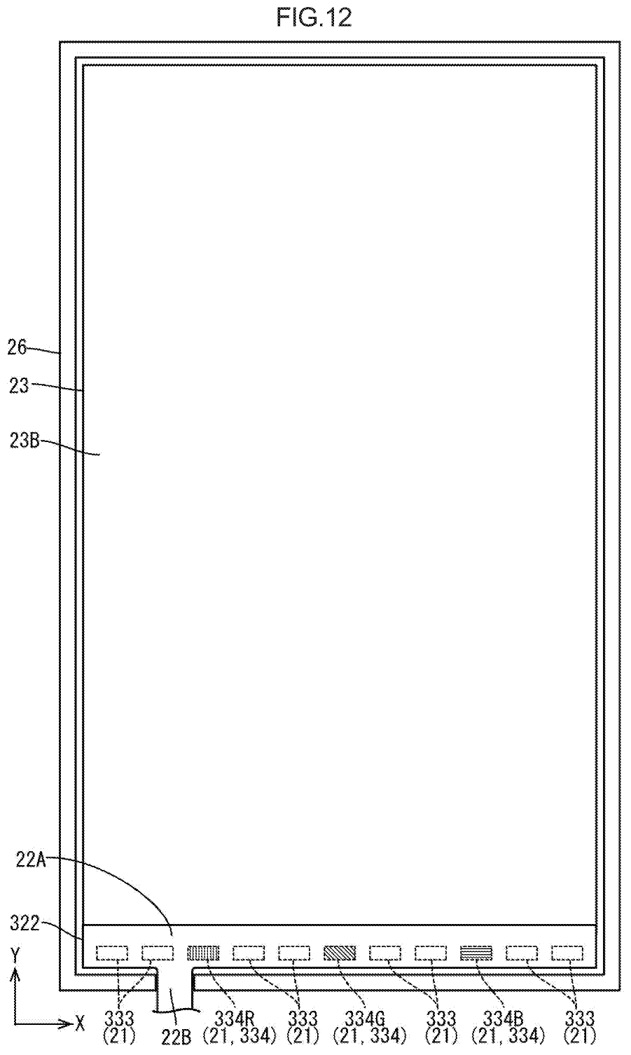

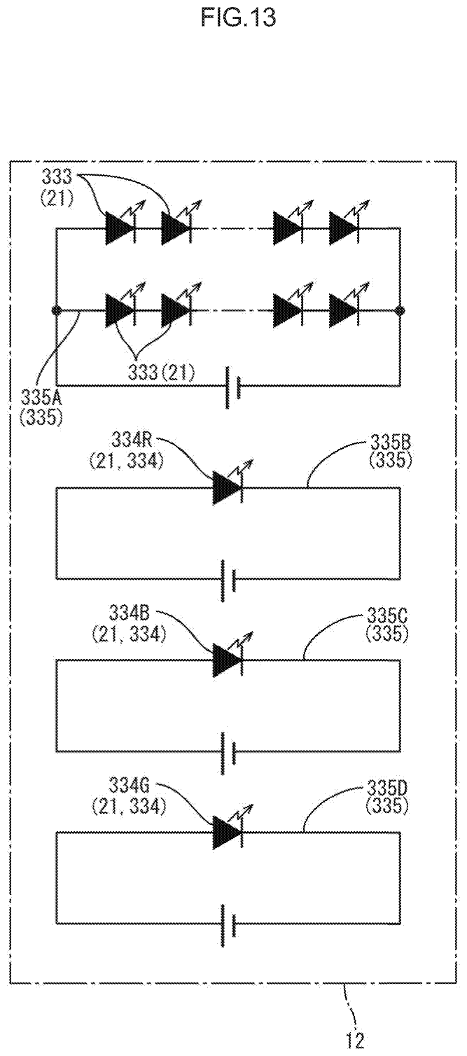

A fourth embodiment will be described with reference to FIG. 12 or 13. In the fourth embodiment, the liquid crystal display device 10 in which the number of kinds of color adjusting LEDs 334 is changed from the second embodiment described above is illustrated. It should be noted that redundant descriptions of a structure, an action and an effect similar to those of the second embodiment described above will be omitted.

The color adjusting LED 334 according to the fourth embodiment includes three kinds: a red LED 334R that emits red light; a blue LED 334 that emits blue light; and a green LED 334G that emits green light. Therefore, the fourth embodiment can be said to have a configuration adaptable whatever color the light transmitted through the white pixel (see FIG. 3) is tinged with. It should be noted that, in FIG. 12, in order to distinguish the three kinds of color adjusting LEDs 334, they are shown by hatching lines differently. The configurations of the red LED 334 and the blue LED 334B are as described in the above second embodiment, and the configuration of the green LED 334G is similar to the color adjusting LED 34 described in the above first embodiment. The respective numbers of red LEDs 334R, blue LEDs 334B and green LEDs 334G installed on the LED board 322 are one, whereas the number of white LEDs 333 installed thereon is more than one (eight in FIG. 12). The red LED 334R, the blue LED 334B and the green LED 334G are disposed such that the white LEDs 333 are divided into four groups by the red LED 334R, the blue LED 334B and the green LED 334G. An LED line portion 335 provided in the LED board 322 includes four systems: a white LED line portion 335A connected to the white LEDs 333; a red LED line portion 335B connected to the one red LED 334R; a blue LED line portion 335C connected to the one blue LED 334B; and a green LED line portion 335D connected to the one green LED 334G.

Next, actions in the fourth embodiment will be described. First, the color tinging the light transmitted through the white pixel is inspected. In inspection, the white pixel is driven in addition to the colored pixels (see FIG. 3) by the pixel controller (see FIG. 5), and simultaneously the white LED 333 is selectively turned on by the LED controller. In this state, the chromaticity associated with the light transmitted through the white pixel is measured, and the tinging color is inspected. As a result, if it is found that the light transmitted through the white pixel exhibits an yellow color, the blue LED 334B that emits light having a blue color that is a complementary color to an yellow color is set to be turned on and the red LED 334R and the green LED 334G are set to be unlit by the LED controller when the white pixel is driven. On the other hand, if it is found that the light transmitted through the white pixel exhibits a cyan color, the red LED 334R that emits light having a red color that is a complementary color to a cyan color is set to be turned on and the blue LED 334B and the green LED 334G are set to be unlit by the LED controller when the white pixel is driven. In addition, if it is found that the light transmitted through the white pixel exhibits a magenta color, the green LED 334G that emits light having a green color that is a complementary color to a magenta color is set to be turned on and the red LED 334R and the blue LED 334B are set to be unlit by the LED controller when the white pixel is driven. At this time, it is preferred that the amount of emitted light of the red LED 334R, the blue LED 334B or the green LED 334G be adjusted in response to the intensity of the color tinging the light transmitted through the white pixel. Further, if the light transmitted through the white pixel exhibits a color between an yellow color and a cyan color, a color between a cyan color and a magenta color or a color between a magenta color and an yellow color, setting of lighting any two or three of the red LED 334R, the blue LED 334B and the green LED 334G appropriately by the LED controller when the white pixel is driven is adoptable. At this time, the ratio of the amounts of emitted light of the color adjusting LEDs 334 to be turned on of the red LED 334R, the blue LED 334B and the green LED 334G is adjustable in response to the color tinging the light transmitted through the white pixel. This enables proper adaptation to whatever tinging color associated with the light transmitted through the white pixel.

### Other Embodiments

The technology described herein is not limited to the embodiments described above in the above description and with reference to the drawings, and, for example, the following embodiments are included in the technical scope of the technology described herein.

(1) The first embodiment described above illustrates the case where the amount of emitted light of the color adjusting LED is adjustable in response to the tone of the white pixel, but, of course, a configuration in which such adjustment is not performed is also acceptable.

(2) In the second embodiment described above illustrates the case where the red LED and the blue LED each of which emits monochromatic light are used as color adjusting LEDs, but, depending on the color tinging the light transmitted through the white pixel, as color adjusting LEDs, a red LED and a green LED may also be used, or a blue LED and a green LED may also be used, each of which emits monochromatic light.

(3) The second embodiment described above illustrates the case where the red LED and the blue LED each of which emits monochromatic light is used as color adjusting LEDs, but any two of an yellow LED, a cyan LED and a magenta LED, each of which emits monochromatic light, may also be used as light adjusting LEDs.

(4) The third embodiment described above illustrates the case where an LED that emits white light tinged with a blue color is used as a color adjusting LED, but, depending on the color tinging the light transmitted through the white pixel, a color adjusting LED that emits white light tinged with a red color may also be used, or a color adjusting LED that emits white light tinged with a green color may also be used.

(5) The third embodiment described above illustrates the case where only one kind of color adjusting LED that emits white light tinged with a blue color is used, but any two or three of a color adjusting LED that emits white light tinged with a blue color, a color adjusting LED that emits white light tinged with a red color, and a color adjusting LED that emits white light tinged with a green color may also be used.

(6) The fourth embodiment described above illustrates the case where the red LED, the blue LED and the green LED each of which emits monochromatic light are used as color adjusting LEDs, an yellow LED, a cyan LED and a magenta LED, each of which emits monochromatic light, may also be used as color adjusting LEDs.

(7) Each embodiment described above illustrates the case where the white LED is provided with a blue LED chip that emits blue light, but a configuration in which the white LED is provided with a violet LED chip that emits violet light or an ultraviolet LED chip that emits ultraviolet radiation is also acceptable. In any case, the white LED is only required to emit white light as a whole as a result of being provided with a phosphor whose excitation light is violet light or ultraviolet radiation.

(8) Each embodiment described above illustrates the case where the white LED is provided with a blue LED chip that emits blue light and a phosphor whose excitation light is blue light, but alternatively the white LED may also be configured to be provided with a blue LED chip that emits blue light, a red LED chip that emits red light, and a green LED chip that emits green light, but not provided with a phosphor, for example.

(9) Each embodiment described above illustrates the case where the white LED has a configuration in which a blue LED chip that emits blue light is sealed with a sealing material containing a phosphor, but alternatively a red LED that emits red light monochromatically, a blue LED that emits blue light monochromatically, and a green LED that emits green light monochromatically may constitute one white LED.

(10) In addition to each embodiment described above, a specific arrangement of white LEDs and color adjusting LEDs on the LED board and/or the number thereof may be changed appropriately. For example, color adjusting LEDs may be provided in the configurations of the first and third embodiments described above, or color adjusting LEDs that emit light tinged with different colors may be provided in the configurations of the second and fourth embodiments. In addition, the number of LEDs installed on the LED board and/or the array interval of the LEDs may be changed appropriately.

(11) Each embodiment described above illustrates the case where InGaN is used as a material for an LED element constituting an LED, but, as other materials for the LED element, for example, GaN, ALGaN, GaP, ZnSe, ZnO, AlGaInP, or the like, may also be used.

(12) In addition to each embodiment described above, a specific order of arrangement of the red pixel, the green pixel, the blue pixel and the white pixel may be changed appropriately.

(13) Each embodiment described above illustrates a side-emission type LED, but a top-emission type LED may also be used as a light source. In addition, a light source (organic EL or the like) other than an LED may also be used.

(14) Each embodiment described above illustrates the backlight device of a one-sided light entry type whose one short-side end face of the outer peripheral end faces of the light guide plate serves as a light entry end face, but a backlight device of a one-sided light entry type whose one long-side end faces of the outer peripheral end faces of the light guide plate serves as a light entry end face is also acceptable. In addition, a backlight device of both side light entry type whose pair of long-side end faces or pair of short-side end faces of the outer peripheral end faces of the light guide plate each serve as a light entry end face is also acceptable. Furthermore, a backlight device of three side light entry type whose any three end faces of the outer peripheral end faces of the light guide plate each serve as a light entry end face or a backlight device of four side light entry type whose all outer peripheral end faces of the light guide plate serve as a light entry end face is also acceptable.

(15) Each embodiment described above illustrates the case where the planar shape of the liquid crystal display device (the liquid crystal panel and/or the backlight device) is a landscape-oriented rectangle, but the planar shape of the liquid crystal display device may be a landscape-oriented rectangle, a square, an ellipse, a circle, a trapezoid, a shape having a curved face partially, or the like.

(16) In addition to each embodiment described above, a specific use or the like of the liquid crystal display device may be changed appropriately.

1. A display device comprising:
a display panel including a plurality of colored pixels exhibiting different colors and a white pixel exhibiting a white color;
a lighting device including at least one white light source configured to emit light to exhibit a white color and at least one color adjusting light source configured to emit light tinged with a color that is a complementary color to a color with which light transmitted through the white pixel is tinged;
a pixel controller configured to control driving of the plurality of colored pixels and the white pixel; and
a light source controller configured to control the at least one white light source and the at least one color adjusting light source to turn on the at least one white light source when the plurality of colored pixels are driven by the pixel controller and to turn on the at least one color adjusting light source in addition to the at least one white light source when the white pixel is driven by the pixel controller in addition to the plurality of colored pixels.

2. The display device according to claim 1, wherein the at least one color adjusting light source emits light exhibiting a red, green or blue color.

3. The display device according to claim 2, wherein the at least one color adjusting light source emits light exhibiting the green color.

4. The display device according to claim 1, wherein the at least one color adjusting light source includes color adjusting light sources configured to emit light exhibiting difference colors.

5. The display device according to claim 4, wherein the light source controller individually controls turn-on and turn-off of the color adjusting light sources.

6. The display device according to claim 1, wherein the at least one color adjusting light source emits white light tinged with a specific color.

7. The display device according to claim 1, wherein
the at least one white light source includes white light sources, and
the number of the at least one color adjusting light source is smaller than the number of the white light sources.

8. The display device according to claim 1, wherein
the pixel controller controls driving of the at least one white pixel to adjust an amount of the light transmitted through the at least one white pixel, and
the light source controller controls the at least one color adjusting light source to adjust an amount of light emitted by the color adjusting light source in response to the amount of the light transmitted through the at least one white pixel.
